(19) United States
(12) Patent Application Publication
(10) Pub. No.: US 2014/0054710 A1
(43) Pub. Date: Feb. 27, 2014

(54) Reduction of Proximity Effects in Field-Effect Transistors with Embedded Silicon-Germanium Source and Drain Regions

(71) Applicants: Youn Sung Choi, Plano, TX (US); Deborah Riley, Murphy, TX (US); Shashank Sureshchandra Ekbote, Allen, TX (US)

(72) Inventors: Youn Sung Choi, Plano, TX (US); Deborah Riley, Murphy, TX (US); Shashank Sureshchandra Ekbote, Allen, TX (US)

(73) Assignee: TEXAS INSTRUMENTS INCORPORATED, Dallas, TX (US)

(21) Appl. No.: 13/591,976

(22) Filed: Aug. 22, 2012

(51) Int. Cl. H01L 21/336; H01L 29/78

(52) U.S. Cl. 257/368; 438/299; 257/E29.255; 257/E21.409

(57) ABSTRACT

An integrated circuit and method of fabricating the same utilizing embedded silicon-germanium (SiGe) source/drain regions, and in which the proximity effect of nearby shallow trench isolation structures is reduced. Embedded SiGe source/drain structures are formed by selective epitaxy into recesses etched into the semiconductor surface, on either side of each gate electrode. The SiGe structures overfill the recesses by at least about 30% of the depth of the recesses, as measured from the interface between the channel region and the overlying gate dielectric at the edge of the gate electrode. This overfill has been observed to reduce proximity effects of nearby shallow trench isolation structures on nearby transistors. Additional reduction in the proximity effect can be obtained by ensuring sufficient spacing between the edge of the gate electrode and a parallel edge of the nearest shallow trench isolation structure.

### CROSS-REFERENCE TO RELATED APPLICATIONS

Not applicable.

### STATEMENT REGARDING FEDERALLY SPONSORED RESEARCH OR DEVELOPMENT

Not applicable.

### BACKGROUND OF THE INVENTION

This invention is in the field of integrated circuit manufacture. Embodiments of this invention are more specifically directed to metal-oxide-semiconductor field-effect transistors (MOSFETs) to which strain engineering technology is applied.

Recent advances in semiconductor technology as applied to integrated circuits include the use of “strain engineering” (or, alternatively, “stress engineering”) in the manufacture of semiconductor device structures. As is fundamental in MOS device technology, the source/drain current (i.e., drive) of a MOS transistor in both the triode and saturation regions is proportional to carrier mobility in the channel region. It has been discovered that the tuning of strain in the crystal lattice of metal-oxide-semiconductor (MOS) transistor channel regions can enhance carrier mobility in those regions. In a general sense, compressive stress enhances hole mobility in the channel region of a p-channel MOS transistor, and tensile stress enhances electron mobility in the channel region of an n-channel MOS transistor.

Various strain engineering approaches are known in the art. According to the approach known as “embedded SiGe” (also referred to as “eSiGe”), source and drain regions of a p-channel MOS transistor structure are etched from the silicon substrate or well region, and are replaced with a silicon-germanium alloy formed by selective epitaxy. By containing as much as 50% (atomic) or more germanium in the crystal lattice, the resulting alloy exhibits a larger lattice constant than does silicon (i.e., the distance between unit cells in the crystal lattice for SiGe is greater than in single-crystal silicon). Embedded SiGe source/drain regions thus apply compressive stress to the adjacent channel region of the p-channel MOS transistor being formed. This compressive stress in the channel increases the hole mobility of the p-channel MOS transistor, and enhances transistor performance. As known in the art, p-channel MOS transistors inherently exhibit lower drive capability than n-channel MOS transistors in typical modern integrated circuits. This weaker p-channel MOS performance can be a limiting factor in CMOS switching speed. Accordingly, eSiGe is an attractive technology for improving the performance of p-channel MOS transistors and thus the overall circuit performance.

FIGS. 1a through 1d illustrate, in cross section, the fabrication of a conventional p-channel MOS transistor including eSiGe source/drain regions. FIG. 1a illustrates a portion of the integrated circuit structure including p-type substrate 4, with n-well 6 formed at selected locations of the surface of substrate 4 by way of ion implantation and diffusion, in the conventional manner. Shallow trench isolation structures 5 are formed by conventional etch and deposition processes, at selected locations of the surface of substrate 4. Dopant implant to adjust the threshold voltage of the eventual transistor is typically also performed at this stage of manufacture. At the stage of the process shown in FIG. 1b, thermal oxidation or deposition of gate dielectric 7 has been followed by the deposition, photolithography, and etch of polysilicon gate structure 8. In this example, hard mask 9 is used to protect polysilicon gate structure 8 from the polysilicon etch, and remains in place at this stage of manufacture.

To form the embedded SiGe source/drain regions in this conventional process, gate dielectric 7 is removed from the source/drain regions, and exposed locations of n-well 6 are etched, at locations outside of gate electrode 8, to form recesses 10 into the underlying single-crystal silicon, as shown in FIG. 1c. Hard mask 9 protects gate structure 8 from the recess etch, but is eroded somewhat by this etch. Recesses 10 at the source/drain regions of the transistor being formed at this location of substrate 4, are thus essentially self-aligned with gate structure 8. Following the recess etch, selective epitaxy of a silicon-germanium alloy is then performed, filling the recesses with embedded SiGe structures 12 as shown in FIG. 1d. SiGe structures 12 are typically doped in situ during the epitaxy, and also by subsequent ion implantation, to become heavily doped p-type, forming the source and drain regions of this transistor. In some conventional structures, the SiGe material is slightly “overfilled” above the recess, for example by about 50 Å for depth of recess 10 on the order of 600 Å, to ensure that all recesses 10 across the wafer are filled. Sidewall dielectric spacers 13 may be formed prior to source/drain implant on the sidewalls of gate structure 8, by deposition and anisotropic etch, to define more lightly-doped source/drain extensions.

By way of further background, a “cap” layer of silicon without Ge dopant may be formed at the surface of SiGe structures 12 in some conventional integrated circuits. This cap layer may be on the order of 50 to 200 Å for a 600 Å deep recess 10, and allows direct react silicidation to form a metal silicide cladding at the source and drain regions of the transistor; the cap layer of silicon is consumed in that silicidation reaction.

As suggested in FIG. 1d, embedded SiGe structures 12 exert compressive strain on channel region 14 underlying gate electrode 8, because the presence of germanium atoms increases the lattice constant of SiGe structures 12 relative to the surrounding silicon. This compressive strain increases the mobility of holes in channel region 14, enhancing the current drive of this p-channel transistor in an “on” state. In the example shown in FIG. 1d, the edges of SiGe structures 12 adjacent to gate electrode 8 are “diamond” shaped. It has been found that this diamond shaped profile provides excellent control of the compressive strain in channel region 14. Other profile shapes, such as a “U-shaped” recess edge, are also known in the art. The shape of these edges is defined by the etch of recesses 10, based on the chemistry and plasma conditions, also as known in the art.

By way of background, as described in Choi et al., “Layout Variations in Advanced MOSFETs: STI-Induced Embedded SiGe Strain Relaxation and Dual-Stress-Liner Boundary Proximity Effect”, Trans. on Electron Devices, Vol. 57, No. 11 (IEEE, November 2010), pp. 2886-91, incorporated by reference, it has been found that shallow trench isolation structures proximate to the gate edge of an p-channel MOS transistor with embedded SiGe source/drain structures relax the strain applied to the transistor channel region by the SiGe material. This strain relaxation is detrimental in that it reduces the effectiveness of the SiGe structures in improving carrier mobility in the transistor. It has also been observed that the undesired relaxation effect caused by the shallow trench isolation structures increases as the spacing between the edge of the isolation structure and the gate edge decreases. FIG. 1d illustrates this spacing SA between the edge of gate electrode 8 and the nearer edge of trench isolation structure 5. Accordingly, as spacing SA shrinks, bringing the edge of trench isolation structure 5 closer to the edge of gate electrode 8, the strain effect of SiGe structures 12 on channel region 14 attenuates. It has been observed, as discussed in the Choi article, that this effect is more pronounced for recesses 10 with diamond-shaped edges than with other edge shapes, such as U-shaped edges.

As known in the art, many modern logic integrated circuits, as well as solid-state memory devices, are now implemented in regular arrays at the transistor level. This regularity is often expressed by arranging gate electrodes of similar size in parallel rows over an area of the integrated circuit. Particularly for minimum feature size gate electrodes, such as in the deep sub-micron regime, this regularity reduces variation due to photolithographic effects, thus improving the controllability of feature sizes and the matching of transistors over the integrated circuit.

However, the proximity effect of shallow trench isolation structures on the effectiveness of embedded SiGe degrades the matching that is otherwise expected from this regularity in transistor array layouts. FIGS. 2a and 2b illustrate, in plan view and cross-section, a regular arrangement of gate electrodes 8 over active region 15 defined by trench isolation structures 5 in which SiGe structures 12 are deployed, defining a group of seven p-channel MOS transistors. As evident from these Figures, seven parallel gate structures 8 are disposed over the single active region 15, within which SiGe structures 12 serving as transistor source and drain regions are disposed between adjacent gate electrodes 8. SiGe structures 12′ are disposed between an edge of shallow trench isolation structures 5 and the outermost ones of gate electrodes 8. As shown in the plan view of FIG. 2a, contacts 13 will be formed through an overlying dielectric layer (not shown) to enable electrical connection to SiGe structures 12. As also shown in FIGS. 2a and 2b, “dummy” gate electrodes 8′ are disposed over shallow trench isolation structures 5, parallel to actual gate electrodes 8 and spaced from the outermost ones of gate electrodes 8 by a spacing substantially the same as that between adjacent ones of gate electrodes 8 over active region 15, to ensure photolithographic uniformity in the patterning and etching of gate electrodes 8.

As mentioned above, it has been observed that the proximity of shallow trench isolation structures 5 parallel to the edges of gate electrodes 8 can degrade the beneficial compressive strain applied by SiGe structures 12, 12′ to transistor channel regions 14. This strain relaxation has been observed to vary with the spacing SA between the edge of shallow trench isolation structures 5 and the near edges of gate electrodes 8. For example, as shown in FIG. 2a, this spacing varies from spacing SA1 between shallow trench isolation structure 5 and the near edge of the nearest one of gate electrodes 8, to spacing SA4 between shallow trench isolation structure 5 and the fourth nearest gate electrode 8. Accordingly, the compressive strain applied to channel regions 14 in these transistors will also vary from least spacing SA1 for the nearest transistor to shallow trench isolation structure 5 to greatest spacing SA4 for the innermost transistor. The degradation in compressive strain for the outermost transistor results in a lower carrier mobility for the transistor at small spacing SA1 relative to the transistor at larger spacings SA2 through SA4, which is reflected in weaker saturation current and higher source-drain resistance in the linear domain for the outermost devices. This difference in performance among these transistors, despite their adjacent locations and similar construction, destroys the transistor matching that is otherwise expected and desired.

By way of further background, FIG. 2c illustrates another known arrangement of gate electrode structures 8 in an integrated circuit utilizing SiGe source/drain structures. In this conventional arrangement, dummy gate electrodes 8′ are formed at the edges of active regions 15a, 15b parallel to the run of the regular parallel gate electrodes 8. SiGe structures 12 are formed after the formation of gate electrodes 8, 8′ with a patterned hard mask protecting polysilicon gate electrodes 8, 8′ from the recess etch. As such, in the structure of FIG. 2c, the portions of active regions 15a, 15b underlying dummy gate electrodes 8′ and immediately adjacent to these parallel edges of shallow trench isolation structures 5 consist of single-crystal silicon rather than SiGe material (and are thus similar to channel regions 14). It is believed that the presence of these silicon regions immediately adjacent to shallow trench isolation structures 5 reduces the proximity effect of those structures on nearby SiGe structures 12. However, as evident from FIG. 2c, two such dummy gate electrodes 8′ are required between adjacent active regions 15a, 15b, necessarily widening the chip area between those two active regions 15a, 15b because of the enforced photolithographic regularity of the spacing G of gate electrodes 8 and dummy gate electrodes 8′. In the arrangement of FIG. 2a, in contrast, only a single dummy gate electrode 8′ is necessitated between adjacent active regions 15. Accordingly, even though the single-crystal silicon at the portions of active regions 15a, 15b immediately adjacent to shallow trench isolation structures 5 may reduce the proximity effect of those structures, that potential benefit comes at a significant chip area penalty.

By way of further background, commonly assigned U.S. Pat. No. 8,183,117, entitled “Device Layout in Integrated Circuits to Reduce Stress from Embedded Silicon-Germanium”, incorporated by reference herein, describes an integrated circuit including one or more MOS transistors in which source and drain regions are formed as embedded silicon-germanium (eSiGe). Guard ring structures in the integrated circuit are formed in single-crystal silicon, rather than in eSiGe. In one example, p-channel MOS transistors have source/drain regions formed in eSiGe, while the locations at which p-type guard rings are formed are masked from the recess etch and the eSiGe selective epitaxy. Defects caused by concentrated crystal strain at the corners of guard rings and similar structures are eliminated.

### BRIEF SUMMARY OF THE INVENTION

Embodiments of this invention provide an integrated circuit and method of fabricating the same having metal-oxide-semiconductor (MOS) transistors with embedded silicon-germanium source/drain structures, in which transistor performance is less sensitive to proximity effects from nearby shallow trench isolation structures.

Embodiments of this invention provide such an integrated circuit and method in which adjacent transistors defined by parallel gate electrodes sharing the same active region can be more precisely matched to one another.

Embodiments of this invention provide such an integrated circuit and method that is especially beneficial for transistors having deep sub-micron gate widths.

Embodiments of this invention provide such an integrated circuit and method that are compatible with direct-react silicidation of the source/drain regions and gate electrodes.

Other objects and advantages of embodiments of this invention will be apparent to those of ordinary skill in the art having reference to the following specification together with its drawings.

Embodiments of this invention may be implemented into an integrated circuit and method of forming the same, in which embedded SiGe structures are formed as the source and drain regions of one or more MOS transistors, for example one or more p-channel MOS transistors. Shallow trench isolation structures define one or more active regions in the integrated circuit. The SiGe material is disposed in recesses on either side of a gate electrode, and extend above the surface of the active region (i.e., from the interface between the silicon channel region and the overlying gate dielectric) by at least about 30% of the depth of the recess into the active region within which the SiGe structure is disposed. A cap layer of silicon may be formed over the SiGe structures for consumption in direct react silicidation; alternatively, additional SiGe beyond the at least about 30% overfill may be provided for consumption in silicidation.

In a regular array of transistors sharing a single active region, in which multiple parallel gate electrodes define matched transistors, the gate electrode closest to a parallel edge of a shallow trench isolation structure is separated from that edge by at least 150 Å to reduce the proximity effect of that isolation structure on the performance of the transistor.

Embodiments of the invention provide uniform transistor performance in a structure and fabrication method compatible with modern deep sub-micron transistor technology, and without inserting a significant chip area penalty.

### BRIEF DESCRIPTION OF THE SEVERAL VIEWS OF THE DRAWING

FIGS. 1a through 1d are cross-sectional views of a conventional metal-oxide-semiconductor (MOS) transistor at various stages of manufacture incorporating conventional embedded SiGe source/drain technology.

FIGS. 2a and 2c are plan views, and FIG. 2b is a cross-sectional view, of a set of conventional MOS transistors incorporating conventional embedded SiGe source/drain technology.

FIGS. 3a and 3b are cross-sectional views, and FIG. 3c is a plan view, of MOS transistors constructed according to an embodiment of the invention.

FIGS. 4a through 4g are cross-sectional views of a MOS transistor at various stages of manufacture according to embodiments of the invention.

FIG. 5 is a flow diagram illustrating the manufacturing process flow for fabricating the transistor of FIGS. 4a through 4g according to embodiments of the invention.

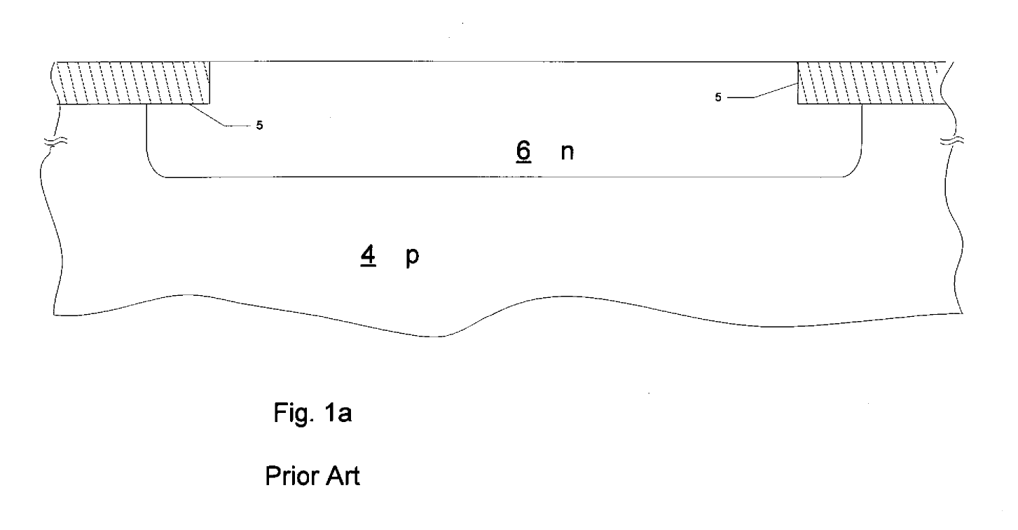

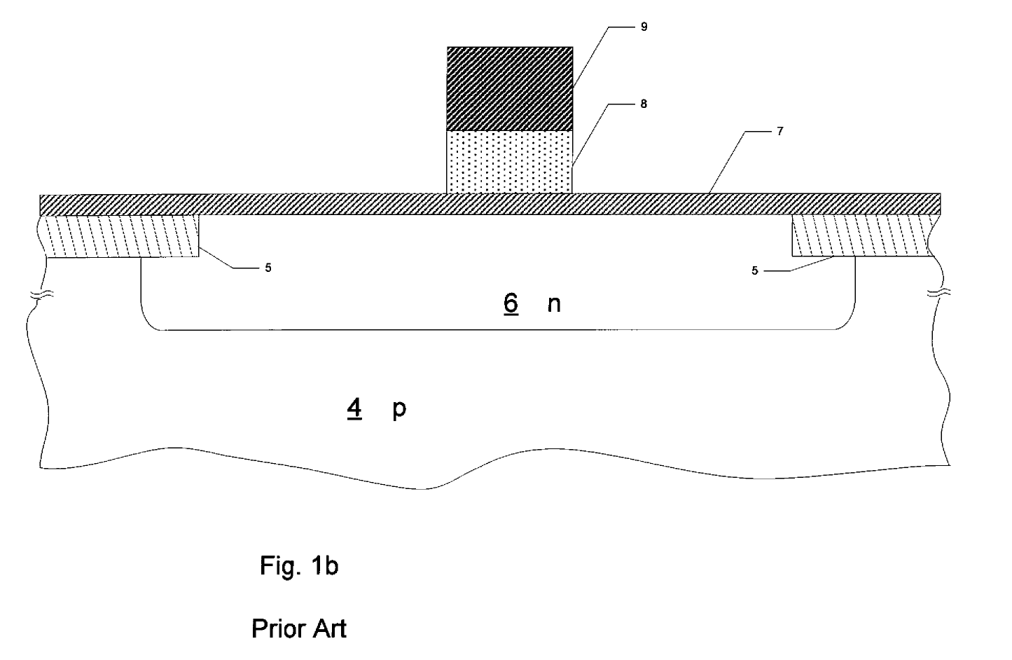

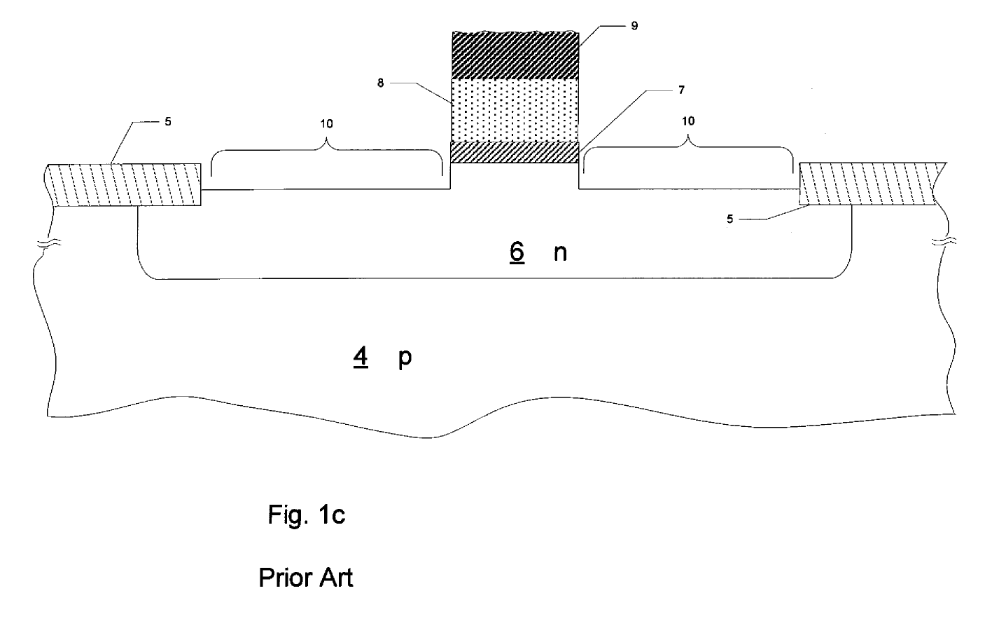

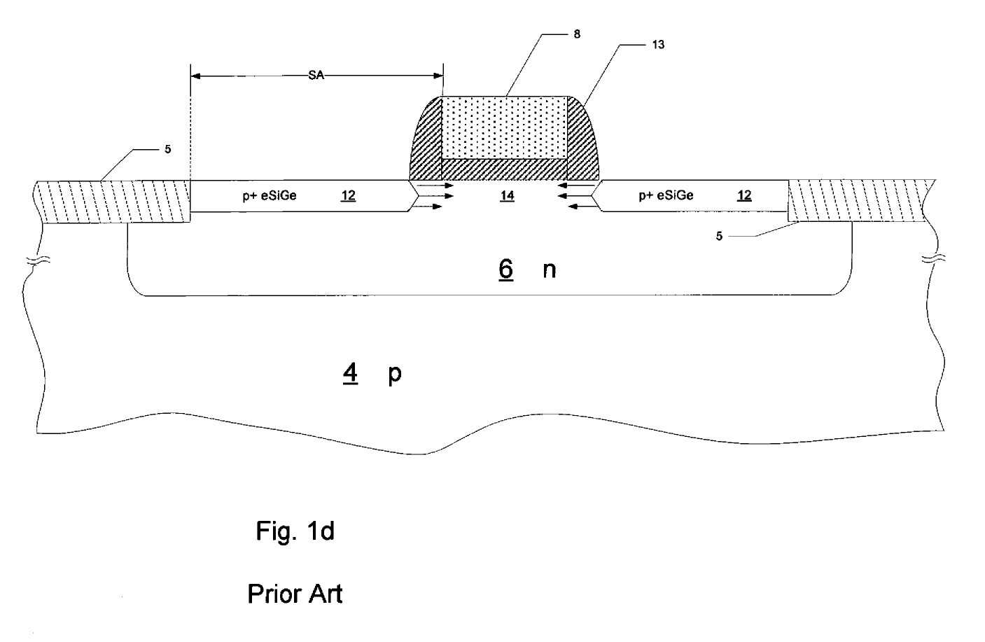

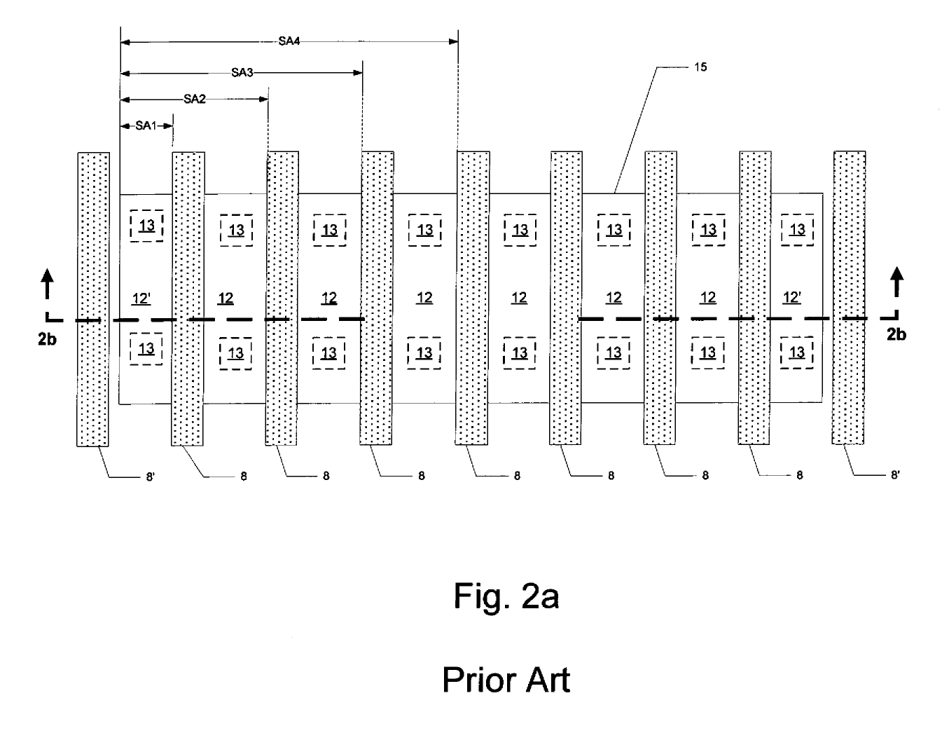

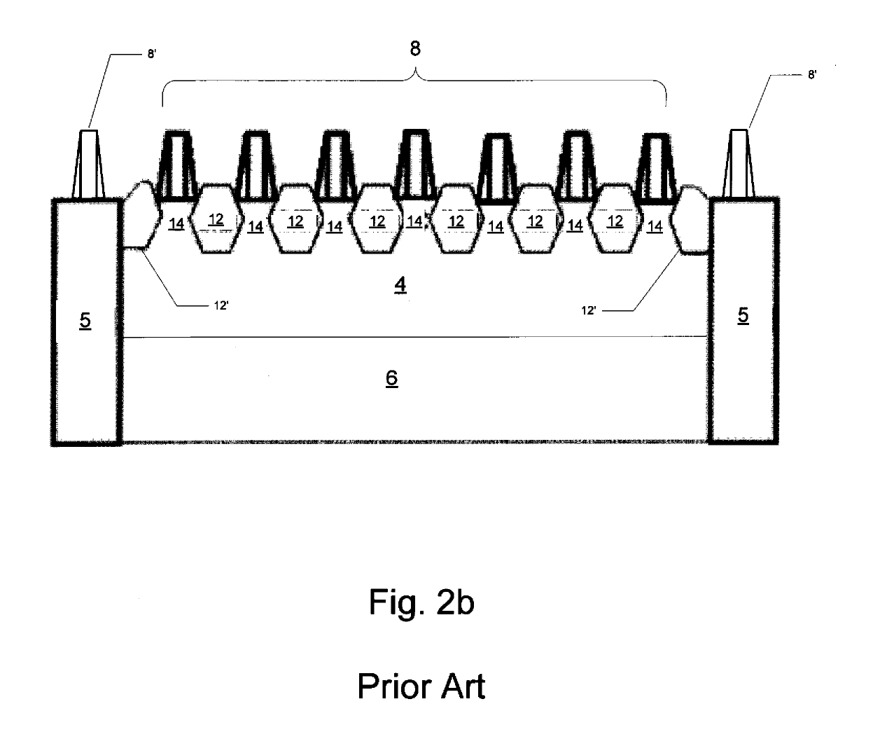

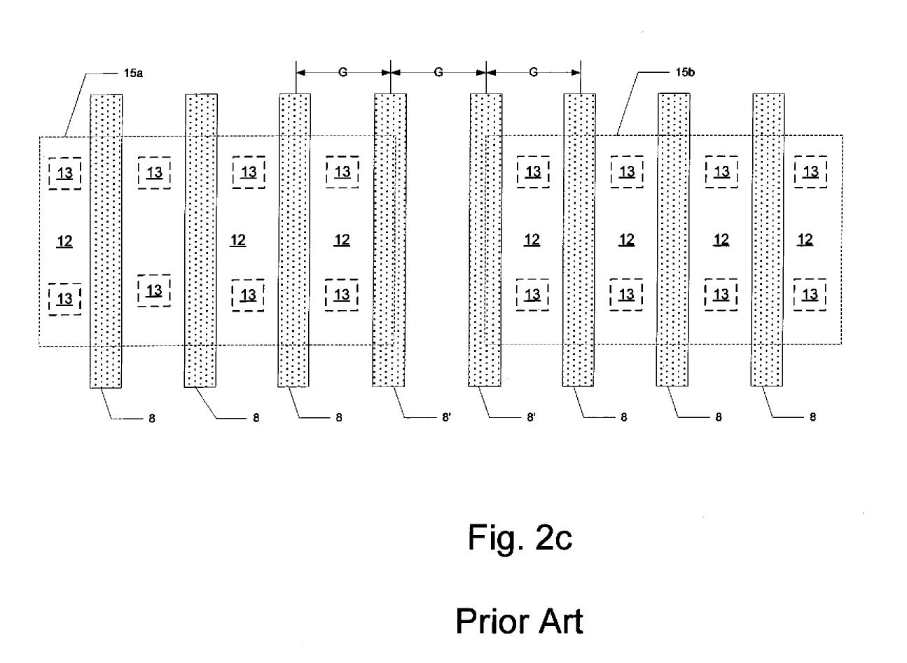

### DETAILED DESCRIPTION OF THE INVENTION

This invention will be described in connection with certain embodiments, namely as implemented into an integrated circuit fabricated according to a metal-oxide-semiconductor (MOS) technology as applied to planar p-channel MOS transistors formed in bulk silicon, as it is contemplated that this invention is especially beneficial in such an application. However, it is also contemplated that this invention may be used in other types of integrated circuits, including n-channel MOS transistors, complementary MOS (CMOS) integrated circuits, integrated circuits fabricated in silicon-on-insulator (SOI) structures, non-planar transistors, other types of field-effect transistors, and the like. Accordingly, it is to be understood that the following description is provided by way of example only, and is not intended to limit the true scope of this invention as claimed.

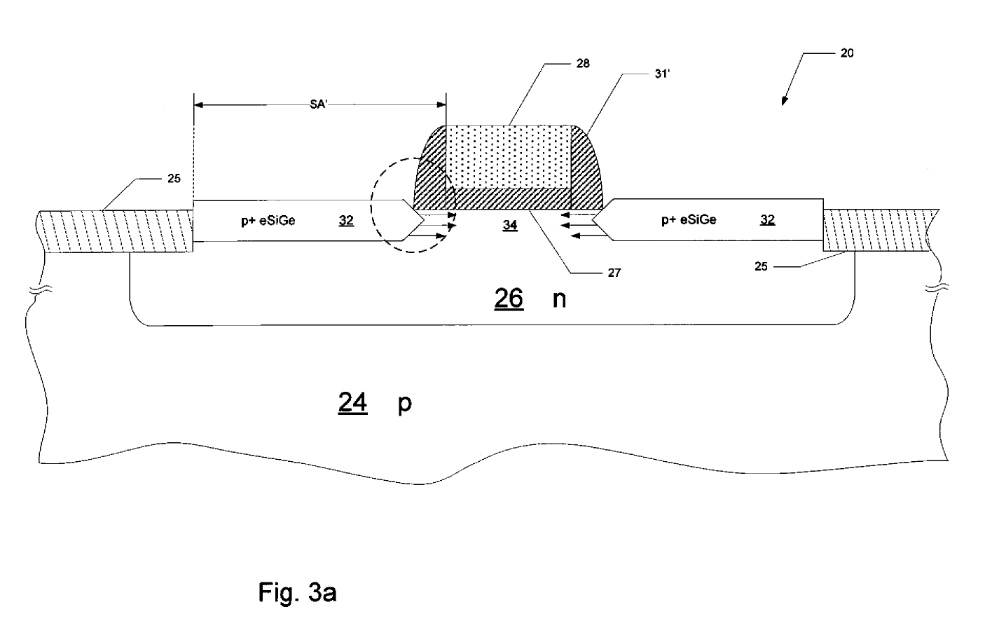

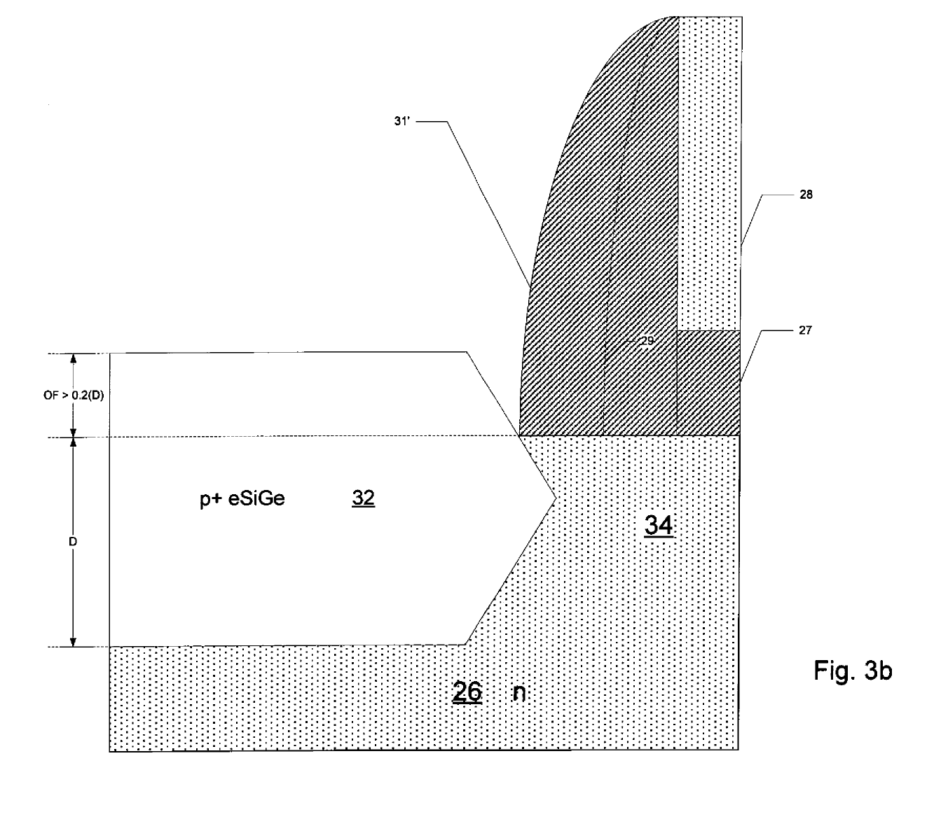

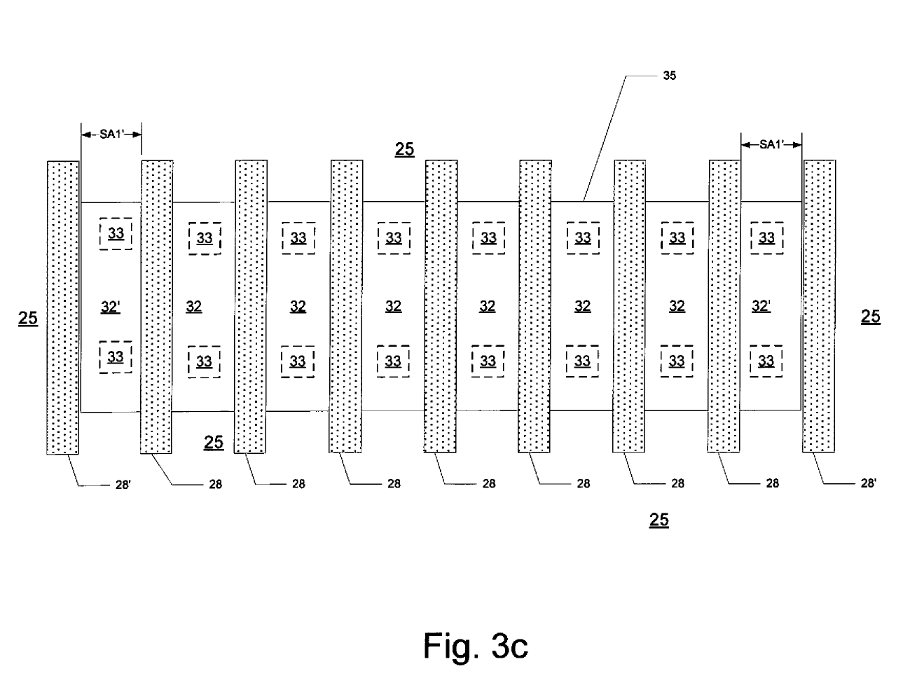

FIGS. 3a and 3b illustrate, in cross-section, the construction of p-channel MOS transistor 20 according to an embodiment of this invention. As shown in FIG. 3a, transistor 20 is formed at a surface of silicon substrate 24. Substrate 24 in this example is p-type bulk silicon material of the desired crystal orientation (e.g., <100> silicon). Since transistor 20 is intended to be a p-channel MOS device, n-type well 26 is defined at a selected location of the surface of substrate 24, typically by way of conventional ion implantation and diffusion anneal. Alternatively, transistor 20 may be formed at the surface of a semiconductor layer disposed over an insulating layer, according to conventional silicon-on-insulator (SOI) technology, or in other similar substrate structures as known in the art.

Transistor 20 is disposed in an active region of the surface of n-well 26 between shallow trench isolation structures 25 (or surrounded by a single such structure 25, depending on the larger-scale layout of the integrated circuit). For purposes of this description, the term “shallow trench isolation structure” refers to an element of dielectric material formed by deposition or the like into a recess etched into a surface of the semiconductor material at which transistors are to be formed; the term “shallow” is intended to convey that the isolation provided by the structure is the electrical isolation of the adjacent surface semiconductor regions on one side of the structure from semiconductor regions on the other side of the structure. Shallow trench isolation structures 25 thus do not necessarily isolate semiconductor structures formed deeper into the semiconductor material, such as buried collectors, diffusion-under-field (DUF) structures, and the like. Typically, shallow trench isolation structures 25 are formed of deposited silicon dioxide, but may alternatively be formed of other dielectric materials. Active regions, at which transistors such as transistor 20 of FIG. 3a are formed, are defined by those surface locations of the semiconductor material (i.e., substrate 24, n-well 26, or a p-type well for n-channel MOS transistors) at which shallow trench isolation structures 25 are not present.

Transistor 20 includes gate electrode 28, which in this embodiment of the invention is formed of p-type doped polycrystalline silicon material; alternatively, gate electrode 28 may be formed of a metal or conductive metal compound, such as titanium, tungsten, tantalum, titanium nitride, tantalum nitride, tungsten nitride, or the like. Gate electrode 28 overlies the surface of n-well 26, with gate dielectric 27 disposed therebetween. Gate dielectric 27 consists of a thin layer of a dielectric material such as silicon dioxide, silicon nitride, or a combination thereof; alternatively, gate dielectric 27 may be a “high-K” material such as HfO₂ or the like. Sidewall hard mask spacers 31′ remain disposed on the sides of gate electrode 28, as will be described further below.

Transistor 20 includes embedded SiGe structures 32, which serve as the source and drain regions of the device. As discussed above, embedded SiGe structures 32 are disposed within recesses of n-well 26, and are constructed from a silicon-germanium alloy such as may be deposited by selective epitaxy. Typically, as known in the art, this alloy may include from as much as about 30% (atomic) to 50% (atomic) or more of germanium, resulting in SiGe structures 32 having a larger lattice constant than single-crystal silicon. As suggested by FIG. 3a, this larger lattice constant of SiGe structures 32 applies a compressive strain applied to the single-crystal silicon of channel region 34 underlying gate electrode 28. That compressive strain has the effect of increasing the mobility of holes in channel region 34, which improves the current conducted by transistor 20 in its “on” state, for a given bias. As shown in the example of FIG. 3a, the edges of SiGe structures 32 adjacent to channel region 34 are “diamond-shaped”, which enables close control of the compressive strain applied to channel region 34. Other profile shapes, such as “U-shaped” recess edges, may alternatively be used if desired. In addition, since transistor 20 is a p-channel MOS transistor, SiGe structures 32 are each heavily-doped p-type, and are thus capable of serving as the source and drain regions for transistor 20.

According to embodiments of this invention, the SiGe alloy forming embedded SiGe structures 32 overfills the recesses in the semiconducting surface of n-well 26 by a significant amount, to such an extent that SiGe structures 32 extend above the surface of channel region 34, and also possibly that of shallow trench isolation structures 25. FIG. 3b illustrates the extent of this overfill according to an embodiment of this invention, by way of a detailed view at the interface between SiGe structure 32 and channel region 34. As shown in FIG. 3b, SiGe structure 32 extends into the surface of n-well 26 to a depth D. Depth D is the depth to which the recess into n-well 26 is etched prior to epitaxy of SiGe structure 32. For the example of a technology in which gate electrode 28 is nominally 32 nm in width, depth D may range from about 400 Å to about 750 Å, as measured from the surface of n-well 26. As a point of reference, this depth D is measured from the interface between channel region 34 and gate dielectric 27, at a point aligned with an edge of gate electrode 28. SiGe structures 32 are overfilled, above this surface reference point, by at least about 20% of depth D, as shown in FIG. 3a. For the example of depth D ranging from about 500 Å to about 600 Å, overfill OF will be at least about 150 Å to about 200 Å above that surface reference point.

Also as shown in FIG. 3b, hard mask sidewall spacer 31′ defines the spacing of the recesses containing SiGe structures 32 from the sides of gate electrode 28. This spacing directly affects the extent to which compressive strain from SiGe structures 32 is applied to the transistor channel region, and as such precise control of this spacing is desirable. As will be described in further detail below, hard mask sidewall spacers 31′ remain from a hard mask layer protecting gate electrode 28 from the etch to form the recesses in which SiGe structures 32 are formed. Optionally, if transistor 20 is formed according to the well-known “lightly-doped drain” technology, spacers 31′ will also include sidewall dielectric spacers 29 that define the drain extension implants.

As known in the art, many integrated circuits increase the conductivity of semiconductor structures, such as source and drain regions and gate electrodes, by forming a metal silicide cladding at the surfaces of these structures. Typically, this silicide cladding is formed by way of direct react silicidation, in which a metal is deposited overall, and the structure subjected to a high temperature anneal to react the deposited metal with underlying silicon to form the metal silicide; a subsequent selective etch removes the unreacted metal from non-silicon structures (e.g., the surfaces of shallow trench isolation structures 25). SiGe structures 32 (and gate electrode 28) of transistor 20 of FIGS. 3a and 3b may be silicide-clad in this manner, if desired. However, according to embodiments of this invention, and as will be further discussed below, such silicidation is performed in a manner that consumes silicon or SiGe material from above the surface of SiGe structures 32. In one embodiment of the invention, selective epitaxy of SiGe structures 32 includes a latter stage in which the germanium-bearing source gas is turned off, resulting in the formation of a single-crystal silicon “cap” layer upon SiGe structures 32; subsequent silicidation of this silicon cap is then performed by deposition of a metal and a high temperature anneal. In another embodiment of the invention, overfill OF of SiGe structures 32 is extended sufficiently far above the surface reference point to allow some consumption of the alloy in silicidation to form a SiGe-silicide cladding. In either case, the remaining non-silicided SiGe alloy material extends above the surface reference point by at least about 30% of depth D to which SiGe structures 32 extend into n-well 26, as shown in FIG. 3b.

Further in the alternative, a silicon “cap” layer formed over SiGe structures 32 during selective epitaxy may remain in place without silicidation. In this alternative also, SiGe structures 32 underlying such a “cap” layer will still extend above the surface reference point by at least about 30% of depth D.

It is believed, and has been observed, according to this invention that this overfill of SiGe alloy material greatly reduces the proximity effect of nearby shallow trench isolation structures 25 on the performance of transistor 20, specifically the proximity effect of structures 25 on the compressive strain applied by SiGe structures 32 to channel region 34. This reduction in the proximity effect has been observed as reduced degradation in transistor source/drain current for those transistors nearest to shallow trench isolation structures 25.

Referring back to FIG. 3a, it has also been observed that maintaining a certain spacing SA′ between the edge of gate electrode 28 and the adjacent parallel edge of the nearest shallow trench isolation structure 25 can further reduce the proximity effect for transistor 20 with overfilled SiGe structures 32 according to embodiments of this invention. For the above-described example of transistor 20 with gate electrode 28 nominally 32 nm in width, depth D of SiGe structures 32 ranging from about 450 Å to about 750 Å and overfill OF of at least about 150 Å to about 200 Å above the surface reference point, a spacing SA′ of at least about 150 Å has been observed to further reduce the proximity effect of shallow trench isolation structures 25 on nearby transistor 20. It is contemplated that this spacing SA′ is larger than that enforced according to conventional methods; for the above example of transistor dimensions, a conventional gate-to-isolation spacing may be about 130 Å or less. This spacing minimum SA′ is contemplated to scale with the nominal gate width dimension, as the manufacturing technology advances.

FIG. 3c illustrates an array of transistors 20 constructed according to embodiments of the invention. In this case, seven parallel gate electrodes 28 run across active region 35, which is defined as a portion of the semiconducting surface surrounded by shallow trench isolation structure 25 as described above. Gate electrodes 28 are spaced at regular intervals from one another, for photolithographic uniformity as discussed above. Dummy gate electrodes 28′ are disposed on both ends of this group of parallel gate electrodes 28, in this case disposed above shallow trench isolation structure 25, to maintain photolithographic regularity for the outer-most ones of active gate electrodes 28. SiGe structures 32 serve as the source and drain regions for these seven transistors, with each interior SiGe structure 32 serving as the source for one transistor and the drain for another. Contact locations 33 are shown in FIG. 3c, at which overlying conductors (not shown) will contact these SiGe source and drain regions. As shown in FIG. 3c, spacing SA1′ is enforced between the edges of outermost gate electrodes 28 and the nearest parallel edge of shallow trench isolation structure 25. In this embodiment of the invention, the combination of overfilled SiGe structures 32 and the additional minimum spacing SA1′ for the outermost devices serves to greatly reduce the proximity effects of shallow trench isolation structures 25 on these outermost transistors. Improved matching among the seven transistors defined by the seven parallel gate structures 28 in FIG. 3c is thus provided by to embodiments of this invention.

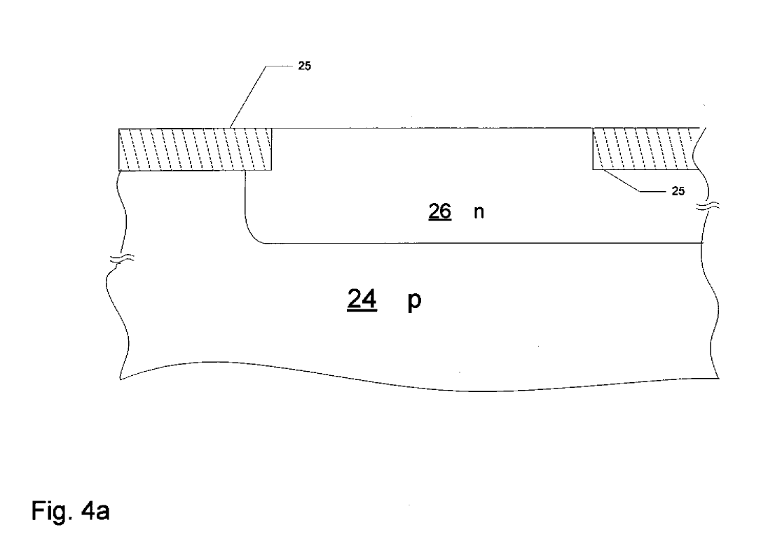

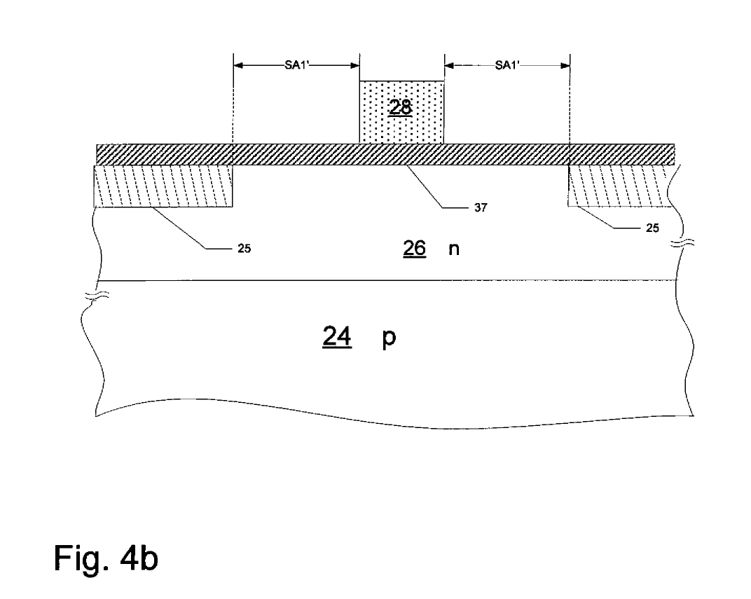

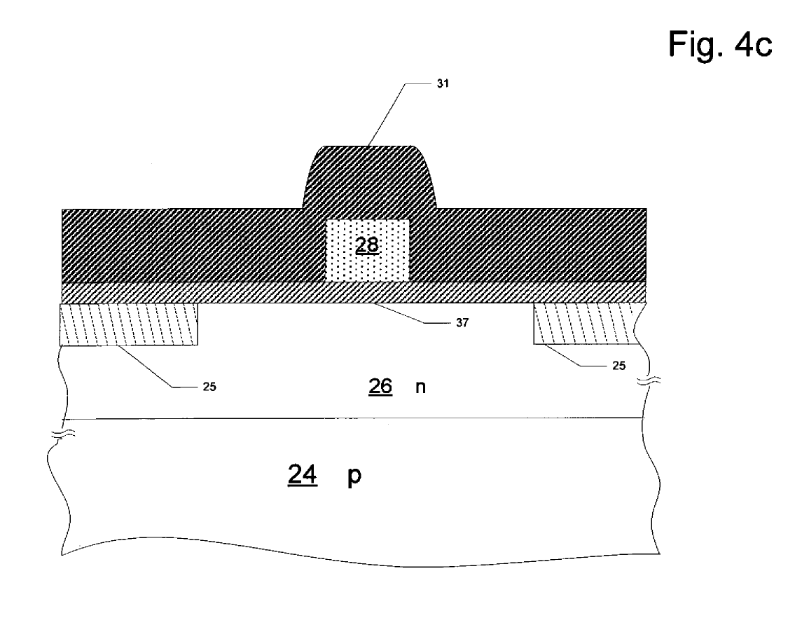

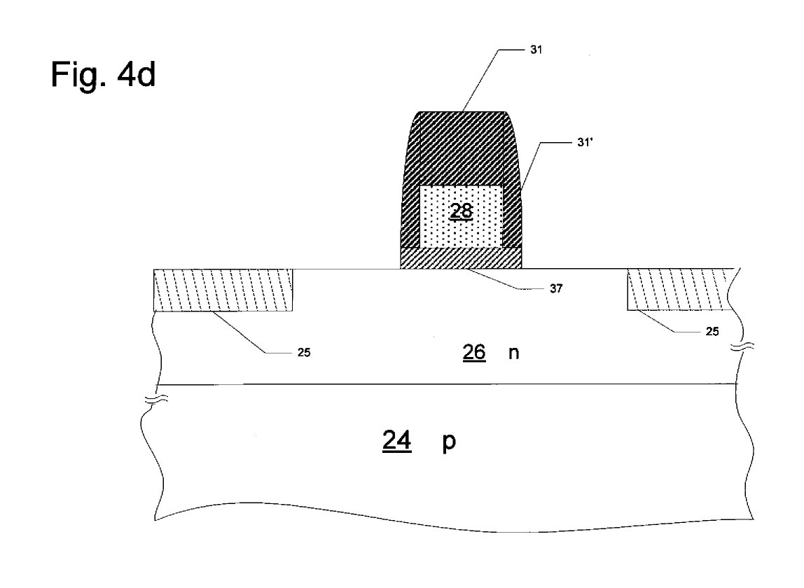

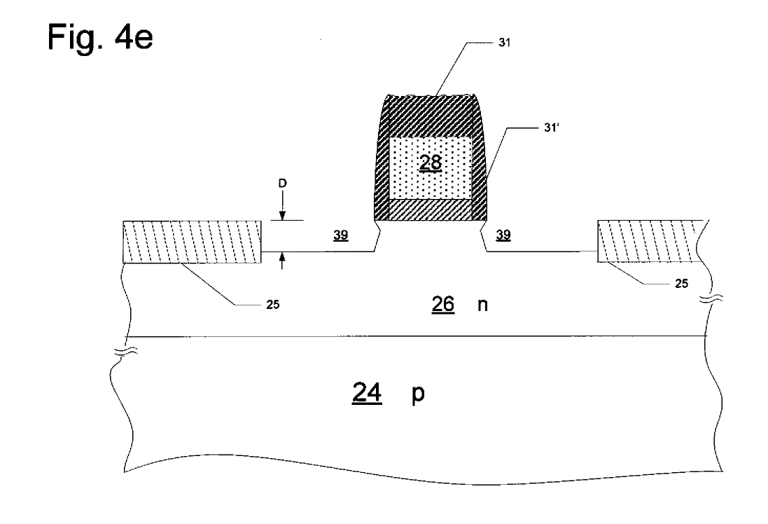

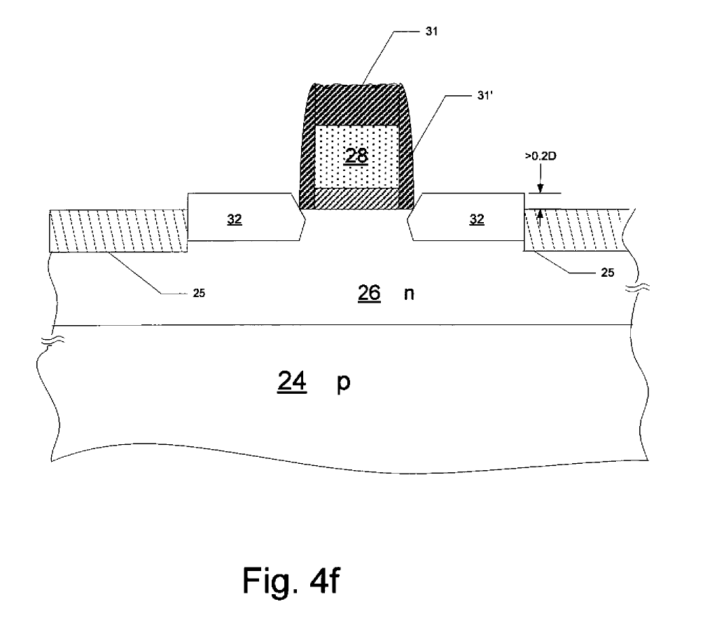

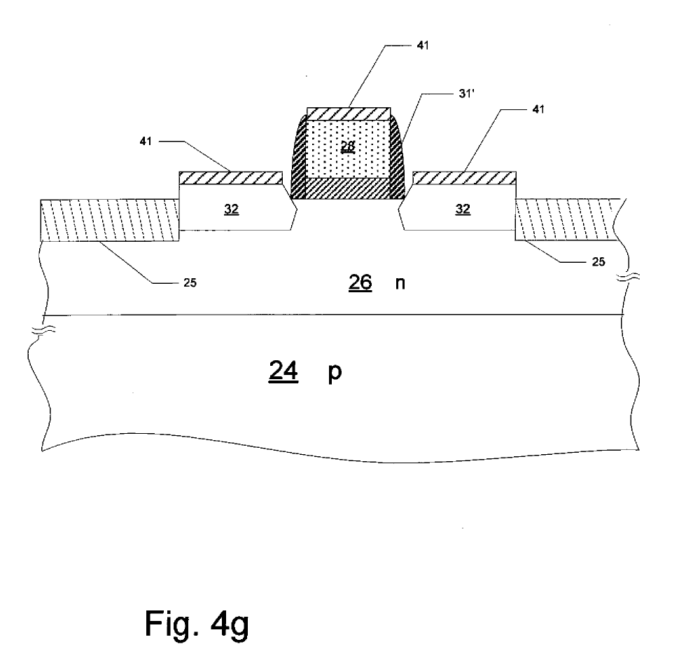

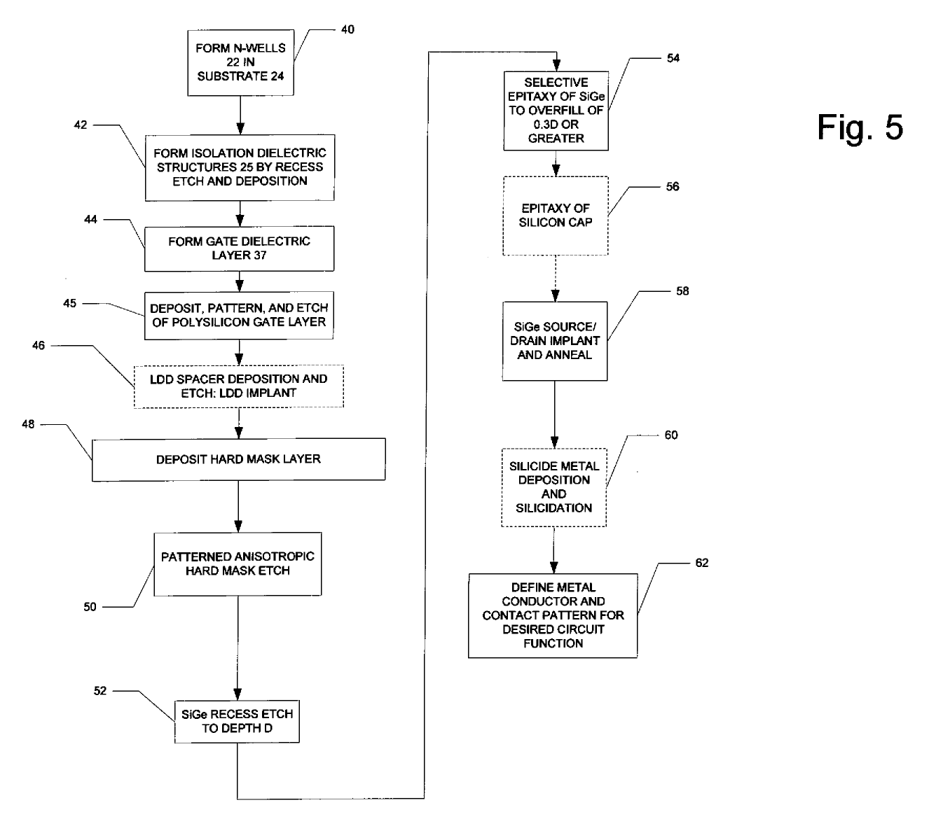

Referring now to FIGS. 4a through 4g, in combination with FIG. 5, a process of fabricating an integrated circuit to include one or more transistors 20 with overfilled SiGe structures 32 according to embodiments of this invention, will now be described in detail. This process is described in a relatively generalized fashion; other additional or alternative process steps may be included as appropriate for the particular manufacturing technology, as will be appreciated by those skilled in the art having reference to this specification. As such, this generalized process is provided by way of example only.

The portion of the manufacturing flow shown in FIG. 5 begins with process 40, in which n-wells 26 are formed at selected locations of substrate 24 in the conventional manner, including the photolithographic definition of the locations of the surface of substrate 24 at which n-wells 26 are to be located, followed by a masked ion implantation and activation anneal. In process 42, shallow trench isolation structures 25 are formed by way of a recess etch followed by deposition of silicon dioxide or another dielectric material, and etchback or other planarization. Dopant implant to adjust the threshold voltage of the eventual transistor is typically also performed at this stage of manufacture. FIG. 4a illustrates, in cross section, a stage in the fabrication of this integrated circuit following processes 40, 42, upon which n-wells 26 and shallow trench isolation structures 25 are defined at selected locations of the surface of substrate 24.

In process 44, gate dielectric film 37 is then formed overall, either by thermal oxidation or nitridation of silicon, or by chemical vapor deposition, depending on the desired material and properties of the transistor gate dielectric. According to embodiments of this invention, gate elements 28 are formed and defined at the desired locations of transistors and dummy gate electrodes 28′, as the case may be, in process 45. For the example of a polysilicon gate structure, process 45 includes the deposition of polycrystalline silicon overall, followed by conventional photolithography and polysilicon etch. The photolithography of gate elements 28 may be performed in the conventional manner by the dispensing of photoresist overall, followed by conventional photolithographic patterning and developing, leaving photoresist mask elements at those locations of the polysilicon layer corresponding to gate electrodes 28, 28′. Etch of the polysilicon layer as protected by the patterned photoresist, also in process 45, then defines the gate element 28, as shown in FIG. 4b.

As shown in FIG. 4b, following process 45, gate electrode 28 overlies gate dielectric layer 37 at a selected location of n-well 26. In the example of FIG. 4b, gate dielectric 37 remains outside of gate electrode 28 to serve as an “etch stop” for polysilicon etch process 48; alternatively, exposed locations of gate dielectric layer 37 may be removed with either or both of hard mask etch process 47 and polysilicon etch process 48. According to this embodiment of the invention, the location of gate electrode 28 defined by the photolithography and etch of process 45 is selected so that gate electrode 28 is spaced from nearby parallel edges of shallow trench isolation structures 25 by at least the minimum spacing SA1′, as shown in FIG. 4b.

Optional process 46 may then be performed if lightly-doped drain extensions are to be formed. If so, sidewall dielectric spacers will be formed in the conventional manner, by deposition of the desired dielectric material (e.g., silicon nitride) overall, followed by an anisotropic etch to remove the dielectric material from flat surfaces, leaving sidewall spacers on the side walls of gate electrode 28. A “halo” implant is then performed, typically as an angled implant so as to reach under the edges of gate electrode 28 (especially considering the yet-to-be-performed recess etch of the source/drain regions, described below), and establish the desired dopant profile. Following formation of the spacers and the halo implant, the sidewall spacers may be removed by an isotropic etch, or may remain in place.

In process 48, hard mask 31 is deposited as a layer overall, with the result as shown in FIG. 4c. This material of hard mask 31 may be silicon dioxide, silicon nitride, or any other material that is relatively resistive to the silicon etch chemistry of a subsequent recess etch, as described below. The thickness of hard mask 31 as deposited is selected to be sufficient to protect gate element 28 and other silicon structures and regions not to be affected by the subsequent recess etch, as well as to define the spacing between the edges of gate electrode 28 and the eventual SiGe structure 32. Following deposition of hard mask 31, photoresist is dispensed over all, and is photolithographically patterned and developed to protect those locations of hard mask layer that are to remain in place for the recess etch. In this embodiment of the invention, those regions of the integrated circuit at which n-channel MOS transistors are to be formed will be protected by hard mask 31, as will gate electrode 28 itself for transistors that are to receive SiGe structures 32. Upon patterning and developing of the photoresist, an anisotropic hard mask etch is performed to remove hard mask 31 where exposed, in process 50. Hard mask etch process 50 is anisotropic so that sidewall hard mask spacers 31′ remain along the sidewalls of gate electrode 28, as shown in FIG. 4d. Sidewall hard mask spacers 31′ will include those LDD spacers formed in process 46 if remaining at this point of the process, as described above.

In either case (i.e., including or not including the LDD spacers), the sidewall hard mask spacers 31′ following etch process 50 will define the placement of eventual SiGe structures 32 from the channel of the transistor. As known in the art for SiGe source/drain structures, compressive strain on the transistor channel region is strongly affected by the distance of the SiGe material to the channel region underlying gate electrode 28. As such, it is desirable to precisely control the thickness of sidewall hard mask spacers 31′, as this thickness defines the edge of the recess to be etched into n-well 26 in this embodiment of the invention. As mentioned above, sidewall hard mask spacers 31′ may include the remaining sidewall spacers from optional LDD process 46; if so, those remaining LDD spacers will contribute to the spacing of the SiGe recesses from the edges of gate electrode 28.

In process 52, the structure is then subjected to a plasma etch to form recesses into n-well 26 at locations not protected by hard mask 31. The plasma conditions of etch process 52 may be selected to define the desired shape of the recesses etched into n-well 26. For example, as discussed above, a “diamond-shaped” recess edge is desirable for precise control of the compressive strain effect. It is contemplated that those skilled in the art can select the appropriate conditions of etch 52 suitable for forming recesses of the desired edge shape and profile. As shown in FIG. 4e, etch process 52 etches recesses 39 into the surface of n-well 26 to a desired depth D, with the desired edge shape on the sides nearest gate electrode 28. Sidewall hard mask spacers 31′ serve as masks for this edge (as do shallow trench isolation structures 25), effectively self-aligning recesses 39 at the desired spacing from gate electrode 28. Hard mask 31 is somewhat eroded by recess etch process 52, as suggested by FIG. 4e.

It is contemplated that the depth of recesses 44 will generally be less than the thickness of adjacent isolation structures 25, for example on the order of one-fourth of that thickness (the depth of recesses 44 are somewhat exaggerated in FIG. 4d, for clarity). For example, the depth of recesses 44 is contemplated to be between 450 and 750 Å, in one example at about 650 Å, for transistor 20 having a nominal gate width of 32 nm.

Selective epitaxy of a silicon-germanium alloy is then performed in process 54, to form embedded silicon-germanium (eSiGe) structures 45 as shown in FIG. 4e. SiGe selective epitaxy process 54 can be carried out in the conventional manner, with the epitaxy being selective in the sense that the silicon-germanium alloy forms and attaches at exposed locations of silicon (i.e., having an exposed crystal structure to which the epitaxial Si—Ge can bond, such as n-well 26 at the bottom of recesses 39), and does not form or attach at locations of the structure at which a dielectric film is disposed. As such, hard mask 31 and sidewall hard mask spacers 31′ prevent the formation and attachment of silicon-germanium to gate electrode 28. The duration of selective epitaxy process 54 is selected so that SiGe structures 32 overfill recesses 39 on either side of the gate stack, with the overfill OV extending at least about 30% of depth D of recesses 39, as shown in FIG. 4f. To the extent that SiGe structures 32 may be thinned by subsequent processing, selective epitaxy process 54 should overfill recesses 39 to an extent that SiGe structures 32 will overfill recesses 39 by at least about 20% of depth D after all subsequent processing.

In optional process 56, a single crystal silicon cap layer is formed over SiGe structures 32 as a later stage of selective epitaxy process 54, by turning off the germanium-bearing source gas during epitaxy once the SiGe alloy is formed to the desired thickness. In one embodiment of the invention, this silicon cap layer over SiGe structures 32 has a thickness in range from about 50 to about 200 Å. This cap layer may remain in place in the finished integrated circuit, for example as a doped layer to which subsequent contact is made. Alternatively, this silicon cap resulting from process 56 may be used in the direct react silicidation of the structure, as described below.

P-type doping of SiGe structures 32 may be performed in situ during selective epitaxy process 54, if appropriate. Alternatively or in addition to that in situ doping, an additional source/drain implant is performed in process 58 to increase the dopant concentration of these eventual source/drain regions of transistor 20. Gate electrodes 28 may also be doped p-type at this time, to ensure proper transistor operation and good conductivity. In process 58, hard mask 31 is removed in the conventional manner, preferably by an anisotropic etch to maintain spacers 31′ if silicidation is to be performed. Process 58 may also include ion implantation of the appropriate dopant and dose of p-type donor species into SiGe structures 32 and the desired activation anneal of the implanted species to the desired junction depth and concentration profile. N-channel transistor regions of the integrated circuit will typically be protected from the p-type implant of process 58 by a photoresist or other mask. Following implant and anneal, p+ source and drain SiGe structures 32 are formed on opposite sides of gate element 28 in n-well 26.

As known in the art and as mentioned above, optional silicidation process 60 includes the deposition of a metal with which the silicide is to be formed, for example titanium, tungsten, tantalum, cobalt, and the like. After deposition of the metal layer, the structure is subjected to a high temperature anneal, also as part of process 60, to cause the deposited metal to react with such silicon (or SiGe) material with which it is in contact, to form a metal silicide compound that clads the underlying structure. FIG. 4g illustrates an example of silicide cladding 41 formed in this manner, at the surfaces of SiGe structures 32 and gate electrode 28. Further in the alternative, silicon cap epitaxy process 58 may be omitted, in which case silicidation process 60 will deposit the metal of the eventual silicide directly over SiGe structures 32, such that the resulting cladding 41 will be a germanium-doped metal silicide.

The structure of FIG. 4g can then be completed, in the conventional manner, by way of the formation and patterning of the appropriate overlying metal conductors, interlevel dielectric or insulator films, and contacts and vias to provide electrical connection among the overlying conductors, and between those conductors and active or conductive elements, all in process 62.

In any case, regardless of whether silicon cap epitaxy process 58 or silicidation process 60 or both are performed, SiGe structures 32 in the resulting integrated circuit overfill the corresponding recesses 39 in n-well 26 to such an extent that the SiGe alloy material underlying any silicidation or cap layer, extends at least about 30% of the recess depth D above the surface of the structure, as measured at the interface between channel region 34 (i.e., the portion of n-well 26 directly underlying gate electrode 28) and gate dielectric 37. It has been observed, according to this invention, that this SiGe overfill serves to reduce the proximity effect of nearby shallow trench isolation structures 25 on the performance of transistors 20, ensuring that the mobility increase sought to be provided by SiGe strain engineering applies in a matched fashion to all transistors in the integrated circuit.

Additional reduction in this proximity effect can be further improved by spacing the edge of transistor gate electrodes 28 sufficiently from the nearest parallel edge of shallow trench isolation structures 25, particularly for the outermost transistors in a regular array of transistors.

As will be apparent to those skilled in the art having reference to this specification, it is contemplated that the method of fabricating transistors according to embodiments of this invention is quite compatible with modern MOS and CMOS manufacturing process flows, without involving significant added cost (e.g., additional photolithography steps).

While this invention has been described according to its embodiments, it is of course contemplated that modifications of, and alternatives to, these embodiments, such modifications and alternatives obtaining the advantages and benefits of this invention, will be apparent to those of ordinary skill in the art having reference to this specification and its drawings. It is contemplated that such modifications and alternatives are within the scope of this invention as subsequently claimed herein.

What is claimed is:

1. A method of fabricating an integrated circuit at a semiconducting surface of a body, comprising:
forming shallow trench isolation structures at selected locations of the surface to define one or more active regions of the surface surrounded by the shallow trench isolation structures;
forming a gate dielectric layer overlying an active region;
then forming one or more gate electrode structures overlying the gate dielectric layer at locations of the active region;
forming and patterning a mask layer at locations overlying the gate electrode structures;
then etching a portion of the active region to form a recess extending to a depth into the surface;
then depositing an alloy of silicon and germanium into the recess, the alloy extending at least about 20% of the depth of the recess above the interface between the surface of the active region and the gate dielectric layer at a point underlying the gate electrode; and
doping the deposited alloy to a first conductivity type.

2. The method of claim 1, further comprising:
forming well regions of a second conductivity type at the surface;
wherein the active region is disposed at one or more of the well regions.

3. The method of claim 1, wherein the depositing step is performed by selective epitaxy.

4. The method of claim 1, wherein the doping step comprises:
doping the deposited alloy in situ during the depositing step.

5. The method of claim 1, wherein the doping step comprises:
implanting dopant ions of the first conductivity type into the deposited alloy.

6. The method of claim 1, wherein the step of forming the mask layer comprises:
depositing a hard mask layer overall; and
anisotropically etching the hard mask layer to provide a hard mask disposed over one or more gate electrode structures overlying the active region, the hard mask including sidewall portions along the sides of the gate electrode structures;
wherein the step of etching a portion of the active region to form the recess into the semiconducting body uses the hard mask as the mask layer.

7. The method of claim 1, wherein the depth of the recess is about 400 to about 750 Å.

8. The method of claim 7, wherein the alloy extends from about 150 Å to about 200 Å above the interface between the surface of the active region and the gate dielectric layer at a point underlying the gate electrode.

9. The method of claim 7, wherein an edge of one of the gate electrodes is disposed at least about 150 Å from the nearest parallel edge of one of the shallow trench isolation structures, measured at the surface.

10. The method of claim 1, further comprising:
forming a layer of polycrystalline silicon over the deposited alloy.

11. The method of claim 10, further comprising:
after the step of forming the layer of polycrystalline silicon, depositing a layer of a metal; and
reacting the metal with the polycrystalline silicon to form a metal silicide cladding.

12. The method of claim 1, further comprising:
after the step of depositing the alloy, depositing a layer of a metal; and
reacting the metal with the alloy to form a metal silicide cladding;
wherein the step of depositing the alloy deposits the alloy sufficiently thick so that, after the reacting step, the unreacted alloy extends at least about 20% of the depth of the recess above the interface between the surface of the active region and the gate dielectric layer at a point underlying the gate electrode.

13. An integrated circuit, comprising:
a body with a semiconducting surface;
shallow trench isolation structures disposed at selected locations of the surface, and defining active regions of the surface therebetween;
a metal-oxide-semiconductor (MOS) transistor formed at an active region of the surface, comprising:
a gate dielectric layer disposed at a location of the active region;
a first gate electrode disposed over a portion of the gate dielectric layer at the active region, the first gate electrode having an edge substantially parallel to an edge of a shallow trench isolation structure defining the active region; and
first and second embedded silicon-germanium structures disposed into the active region to a selected depth on opposite sides of the first gate electrode, each extending at least about 20% of the selected depth above the interface between the surface of the active region and the gate dielectric layer at a point underlying the first gate electrode.

14. The integrated circuit of claim 13, further comprising:
a well region disposed at the surface of the active region and extending into the body, the well region of opposite conductivity type from that of the first and second silicon-germanium structures;
wherein the active region is disposed within the well region.

15. The integrated circuit of claim 13, wherein the first and second embedded silicon-germanium structures are doped p-type.

16. The integrated circuit of claim 13, further comprising:
at least one additional gate electrode disposed over a portion of the gate dielectric layer at the active region, each of the at least one additional gate electrode running parallel to the first gate electrode; and
embedded silicon-germanium structures disposed into the active region to a selected depth on opposite sides of each of the gate electrodes, each extending at least about 20% of the selected depth above the interface between the surface of the active region and the gate dielectric layer at a point underlying the gate electrode;
wherein each of a plurality of embedded silicon-germanium structures are associated with a pair of adjacent ones of the gate electrodes.

17. The integrated circuit of claim 16, wherein an edge of a nearest one of the gate electrodes to a shallow trench isolation structure is disposed at least about 150 Å from the nearest parallel edge of that shallow trench isolation structure, measured at the surface of the active region.

18. The integrated circuit of claim 13, wherein the selected depth of the first and second embedded silicon-germanium structures is about 400 to about 750 Å.

19. The integrated circuit of claim 18, wherein the first and second embedded silicon-germanium structures extend from about 150 Å to about 200 Å above the interface between the surface of the active region and the gate dielectric layer at a point underlying the gate electrode.

20. The integrated circuit of claim 13, further comprising:
polycrystalline silicon disposed over the first and second embedded silicon-germanium structures.

21. The integrated circuit of claim 13, further comprising:
a metal silicide cladding disposed over the first and second embedded silicon-germanium structures.
